(19) United States
(12) Patent Application Publication
(10) Pub. No.: US 2021/0184794 A1
(43) Pub. Date: Jun. 17, 2021

(54) GLITCH FREE AUDIO IN NOISY ENVIRONMENTS

(71) Applicant: QUALCOMM Incorporated, San Diego, CA (US)

(72) Inventors: Vishal Agarwal, Ramnagar (IN); Giriraj Goyal, Bangalore (IN)

(21) Appl. No.: 16/714,030

(22) Filed: Dec. 13, 2019

(51) Int. Cl. H04L 1/00; H03M 13/09; H04L 1/18; H04L 5/00

(52) U.S. Cl. CPC H04L 1/0061; H03M 13/09; H04L 5/0055; H04L 1/1819; H04L 1/0083

(57) ABSTRACT

Methods, systems, and devices for wireless communications are described. A device may receive a first packet including a set of segments. A segment of the set of segments may include a cyclic redundancy check (CRC). The device may determine a corruption of one or more segments of the first packet, and process the one or more segments based on the corruption. The device may receive a second packet based on the corruption of the one or more segments of the first packet. The second packet may include one or more of the segments of the first packet. The device may process the one or more segments of the first packet received in the second packet, and transmit a positive acknowledgment indicating a reception of all segments of the set of segments based on the first packet and the second packet.

### FIELD OF TECHNOLOGY

The following relates generally to wireless communications and more specifically to glitch free audio in noisy environments.

### BACKGROUND

Multimedia systems are widely deployed to provide various types of multimedia communication content such as voice, video, packet data, messaging, broadcast, and so on. These multimedia systems may be capable of processing, storage, generation, manipulation and rendition of multimedia information. Examples of multimedia systems include wireless communications systems, entertainment systems, information systems, virtual reality systems, model and simulation systems, and so on. These systems may employ a combination of hardware and software technologies to support processing, storage, generation, manipulation and rendition of multimedia information, for example, such as capture devices, storage devices, communication networks, computer systems, and display devices.

As demand for multimedia communication efficiency increases, some multimedia systems, may fail to provide satisfactory multimedia operations for multimedia communications, and thereby may be unable to support high reliability and low latency multimedia operations, among other examples.

### SUMMARY

The described techniques may relate to configuring a communication device, which may be a user equipment (UE), to support multimedia streaming (e.g., in the form of packets), and more specifically glitch-free audio and/or video streaming in a multimedia system. In some examples, the described techniques may be used to configure the communication device (e.g., a transmitter device) to generate a packet and segment the packet into a set of segments. The communication device may append error-detection code to one or more segments of the segmented packet, and a receiving communication device may confirm the presence or absence of errors in the packet based on the error-detection code. For example, the communication device may append a cyclic redundancy check (CRC) to one or more segments of the segmented packet, prior to transmitting the packet via a packet-based protocol. The communication device may use the CRC as an error-detection code to detect errors caused to the packet by noise or interference in the multimedia system. The packet-based protocol may be an audio profile, a video profile, or a combination thereof. In an example, the packet-based protocol may be an advanced audio distribution profile (A2DP) or a logical link control and adaptation protocol (L2CAP).

In some examples, the described techniques may be used to configure the communication device (e.g., a receiver device) to verify the CRC appended to the one or more segments of the segmented packet by recording which segments have been received successfully or unsuccessfully based on decoding the CRC. The communication device may provide feedback (e.g., a positive acknowledgement, a negative acknowledgment) indicating receipt of the packet. In some examples, the communication device may receive a retransmission of the packet based on the feedback. While waiting for the retransmission, the communication device may use one or more successfully received segments (e.g., audio frames) irrespective of whether all segments of the packet have been successfully received. The described techniques may thus include features for improvements to power consumption, spectral efficiency, higher data rates and, in some examples, may promote enhanced efficiency for high reliability and low latency multimedia streaming operations in multimedia communications systems, among other benefits.

A method of wireless communications at a device is described. The method may include receiving, during a first period, a first packet including a set of segments, where a segment of the set of segments includes a CRC, determining a corruption of one or more segments of the set of segments of the first packet based on the receiving, processing the one or more segments of the set of segments of the first packet based on the corruption of the one or more segments of the first packet, receiving, during a second period, a second packet based on the corruption of the one or more segments of the set of segments of the first packet, the second packet including one or more of the segments of the set of segments of the first packet, processing the one or more segments of the set of segments of the first packet received in the second packet, and transmitting a positive acknowledgment indicating a reception of all segments of the set of segments based on the first packet and the second packet.

An apparatus for wireless communications is described. The apparatus may include a processor, memory coupled with the processor, and instructions stored in the memory. The instructions may be executable by the processor to cause the apparatus to receive, during a first period, a first packet including a set of segments, where a segment of the set of segments includes a CRC, determine a corruption of one or more segments of the set of segments of the first packet based on the receiving, process the one or more segments of the set of segments of the first packet based on the corruption of the one or more segments of the first packet, receive, during a second period, a second packet based on the corruption of the one or more segments of the set of segments of the first packet, the second packet including one or more of the segments of the set of segments of the first packet, process the one or more segments of the set of segments of the first packet received in the second packet, and transmit a positive acknowledgment indicating a reception of all segments of the set of segments based on the first packet and the second packet.

Another apparatus for wireless communications is described. The apparatus may include means for receiving, during a first period, a first packet including a set of segments, where a segment of the set of segments includes a CRC, determining a corruption of one or more segments of the set of segments of the first packet based on the receiving, processing the one or more segments of the set of segments of the first packet based on the corruption of the one or more segments of the first packet, receiving, during a second period, a second packet based on the corruption of the one or more segments of the set of segments of the first packet, the second packet including one or more of the segments of the set of segments of the first packet, processing the one or more segments of the set of segments of the first packet received in the second packet, and transmitting a positive acknowledgment indicating a reception of all segments of the set of segments based on the first packet and the second packet.

A non-transitory computer-readable medium storing code for wireless communications at a device is described. The code may include instructions executable by a processor to receive, during a first period, a first packet including a set of segments, where a segment of the set of segments includes a CRC, determine a corruption of one or more segments of the set of segments of the first packet based on the receiving, process the one or more segments of the set of segments of the first packet based on the corruption of the one or more segments of the first packet, receive, during a second period, a second packet based on the corruption of the one or more segments of the set of segments of the first packet, the second packet including one or more of the segments of the set of segments of the first packet, process the one or more segments of the set of segments of the first packet received in the second packet, and transmit a positive acknowledgment indicating a reception of all segments of the set of segments based on the first packet and the second packet.

In some examples of the method, apparatuses, and non-transitory computer-readable medium described herein, transmitting a negative acknowledgement based on the corruption of the one or more segments of the first packet, where receiving the second packet includes: receiving, during the second period, the second packet based on the negative acknowledgement.

In some examples of the method, apparatuses, and non-transitory computer-readable medium described herein, each segment of the set of segments includes a CRC.

Some examples of the method, apparatuses, and non-transitory computer-readable medium described herein may further include operations, features, means, or instructions for determining that each segment of the set of segments of the first packet includes a CRC, and decoding the CRC of each segment of the set of segments, where determining the corruption of the one or more segments of the set of segments of the first packet may be based on the decoding.

Some examples of the method, apparatuses, and non-transitory computer-readable medium described herein may further include operations, features, means, or instructions for decoding the CRC of the segment of the set of segments of the first packet, decoding an additional CRC of the first packet, and where determining the corruption of one or more segments of the set of segments of the first packet may be based on one or more of decoding the CRC of the segment of the set of segments or decoding the additional CRC of the first packet.

Some examples of the method, apparatuses, and non-transitory computer-readable medium described herein may further include operations, features, means, or instructions for determining a successful decoding of the CRC of the segment of the set of segments of the first packet, determining an unsuccessful decoding of an additional CRC of the first packet, refraining from dropping the first packet based on the successful decoding of the CRC of the segment of the set of segments of the first packet, and where processing the one or more segments of the set of segments of the first packet may be based on the refraining.

In some examples of the method, apparatuses, and non-transitory computer-readable medium described herein, processing the one or more segments of the set of segments of the first packet may include operations, features, means, or instructions for outputting a representation of the segment of the set of segments of the first packet based on the successful decoding of the CRC of the segment.

In some examples of the method, apparatuses, and non-transitory computer-readable medium described herein, processing the one or more segments of the set of segments of the first packet may include operations, features, means, or instructions for determining an unsuccessful decoding of a second CRC of a second segment of the set of segments of the first packet, and discarding the second segment based on the unsuccessful decoding of a second CRC.

In some examples of the method, apparatuses, and non-transitory computer-readable medium described herein, processing the one or more segments of the set of segments of the first packet may include operations, features, means, or instructions for determining an unsuccessful decoding of a second CRC of a second segment of the set of segments of the first packet, and performing a packet loss concealment operation based on the unsuccessful decoding of a second CRC.

Some examples of the method, apparatuses, and non-transitory computer-readable medium described herein may further include operations, features, means, or instructions for aggregating the one or more segments of the set of segments of the first packet and the one or more of the segments of the set of segments of the first packet received in the second packet, and where the aggregating occurs at an upper layer of the device.

Some examples of the method, apparatuses, and non-transitory computer-readable medium described herein may further include operations, features, means, or instructions for determining a sequence associated with one or more of the first packet or the second packet based on header information of one or more of the first packet or the second packet, and where transmitting the positive acknowledgement may be based on the sequence associated with one or more of the first packet or the second packet.

Some examples of the method, apparatuses, and non-transitory computer-readable medium described herein may further include operations, features, means, or instructions for identifying the header information in a real-time transport protocol header associated with one or more of the first packet or the second packet.

In some examples of the method, apparatuses, and non-transitory computer-readable medium described herein, one or more of the first packet or the second packet includes an A2DP packet.

In some examples of the method, apparatuses, and non-transitory computer-readable medium described herein, one or more of the first packet or the second packet includes an audio packet or a video packet, or a combination thereof.

A method of wireless communications at a device is described. The method may include generating a packet, segmenting the packet into a set of segments, appending a CRC to one or more segments of the set of segments based on segmenting the packet into the set of segments, and transmitting, during a first period, the packet including the set of segments to a device.

An apparatus for wireless communications is described. The apparatus may include a processor, memory coupled with the processor, and instructions stored in the memory. The instructions may be executable by the processor to cause the apparatus to generate a packet, segment the packet into a set of segments, append a CRC to one or more segments of the set of segments based on segmenting the packet into the set of segments, and transmit, during a first period, the packet including the set of segments to a device.

Another apparatus for wireless communications is described. The apparatus may include means for generating a packet, segmenting the packet into a set of segments, appending a CRC to one or more segments of the set of segments based on segmenting the packet into the set of segments, and transmitting, during a first period, the packet including the set of segments to a device.

A non-transitory computer-readable medium storing code for wireless communications at a device is described. The code may include instructions executable by a processor to generate a packet, segment the packet into a set of segments, append a CRC to one or more segments of the set of segments based on segmenting the packet into the set of segments, and transmit, during a first period, the packet including the set of segments to a device.

Some examples of the method, apparatuses, and non-transitory computer-readable medium described herein may further include operations, features, means, or instructions for receiving a negative acknowledgement associated with transmitting the packet, transmitting, during a second period, a second packet to the device, the second packet including the set of segments transmitted in the packet, and where transmitting the second packet may be based on receiving the negative acknowledgement.

Some examples of the method, apparatuses, and non-transitory computer-readable medium described herein may further include operations, features, means, or instructions for appending an additional CRC to the first packet.

Some examples of the method, apparatuses, and non-transitory computer-readable medium described herein may further include operations, features, means, or instructions for receiving a positive acknowledgment indicating a reception of all segments of the set of segments based on the first packet and the second packet, and refraining from transmitting a third packet including one or more of the segments of the set of segments of the first packet or the second packet.

In some examples of the method, apparatuses, and non-transitory computer-readable medium described herein, each segment of the set of segments includes a separate CRC.

### BRIEF DESCRIPTION OF THE DRAWINGS

FIG. 1 illustrates an example of a multimedia system that supports glitch free audio in noisy environments in accordance with aspects of the present disclosure.

FIGS. 2 and 3 illustrate examples of communication configurations that support glitch free audio in noisy environments in accordance with aspects of the present disclosure.

FIGS. 4 and 5 show block diagrams of devices that support glitch free audio in noisy environments in accordance with aspects of the present disclosure.

FIG. 6 shows a block diagram of a communications manager that supports glitch free audio in noisy environments in accordance with aspects of the present disclosure.

FIG. 7 shows a diagram of a system including a device that supports glitch free audio in noisy environments in accordance with aspects of the present disclosure.

FIGS. 8 and 9 show flowcharts illustrating methods that support glitch free audio in noisy environments in accordance with aspects of the present disclosure.

### DETAILED DESCRIPTION

A device may support audio streaming or video streaming, or a combination thereof using packet-based protocols such as, an advanced audio distribution profile (A2DP), a logical link control and adaptation protocol (L2CAP), among other examples. In some cases, the device may experience issues with the audio streaming or video streaming, or both due to interference in a multimedia system (e.g., a physical environment). For example, a device (e.g. a smartphone) streaming audio (in the form of audio packets) to another device (e.g., a Bluetooth headset) may experience a high bit error rate due to noise in the physical environment. In some examples, the interference may be due to multiple active communication links, such as Wi-Fi links in the multimedia system. As a result, the device may have to perform multiple retransmissions of the audio packets before an entirety of the audio packets is successfully received at the other device (e.g., the Bluetooth headset). For example, the device may have to perform 10-15 retransmission for an A2DP packet. As demand for multimedia communication efficiency increases, some multimedia systems, may fail to provide acceptable multimedia operations for multimedia communications, and thereby may be unable to support high reliability and low latency multimedia operations, among other examples.

To address the above shortcomings, the device may support glitch-free multimedia streaming in the multimedia system. For example, the device may be configured to generate a packet, segment the packet into a set of segments (e.g., a set of audio frames, a set of video frames, or both), and transmit the packet including the set of segments. In other words, the device may divide a packet into multiple frames, and transmit all the frames in the single packet. The device may thus be configured to support, for multimedia applications, segmented transmission of packets containing multiple frames. The device may append a cyclic redundancy check (CRC) to one or more segments of the segmented packet, prior to transmitting the packet via a packet-based protocol. The device may use the CRC as an error-detection code to detect errors caused to the packet by noise or interference in the multimedia system. The packet-based protocol may be an audio profile, a video profile, or a combination thereof. In an example, the packet-based protocol may be an advanced audio distribution profile (A2DP) or a logical link control and adaptation protocol (L2CAP).

In some examples, the device (e.g., a receiver device) may verify the CRC appended to the one or more segments of the segmented packet by recording which segments have been received successfully or unsuccessfully based on decoding the CRC. The device may provide feedback (e.g., a positive acknowledgement, a negative acknowledgment) indicating receipt of the packet. In some examples, the device may receive a retransmission of the packet based on the feedback. While waiting for the retransmission, the device may use any successfully received segments (e.g., frames) irrespective of whether all segments of the packet have been successfully received. The described techniques may thus include features for improvements to power consumption, spectral efficiency, higher data rates and, in some examples, may promote enhanced efficiency for high reliability and low latency multimedia streaming operations in multimedia communications systems, among other benefits.

Particular aspects of the subject matter described in this disclosure may be implemented to realize one or more of the following potential advantages. The techniques employed by the described communication devices may provide benefits and enhancements to the operation of the communication devices. For example, operations performed by the described communication devices may provide improvements to multimedia communications, and more specifically to multimedia streaming in a multimedia system. In some examples, configuring the described communication devices with processing a packet comprising a set of segments, where one or more segments of the set include a CRC, and using any successfully received segments (e.g., audio frames) irrespective of whether all segments of the packet have been successfully received may support improvements to power consumption, spectral efficiency, higher data rates and, in some examples, may promote enhanced efficiency and low latency for multimedia operations (e.g., audio streaming, video streaming), among other benefits.

Aspects of the disclosure are initially described in the context of multimedia systems. Aspects of the disclosure are then illustrated by and described with reference to communication configurations that relate to glitch free audio in noisy environments. Aspects of the disclosure are further illustrated by and described with reference to apparatus diagrams, system diagrams, and flowcharts that relate to glitch free audio in noisy environments.

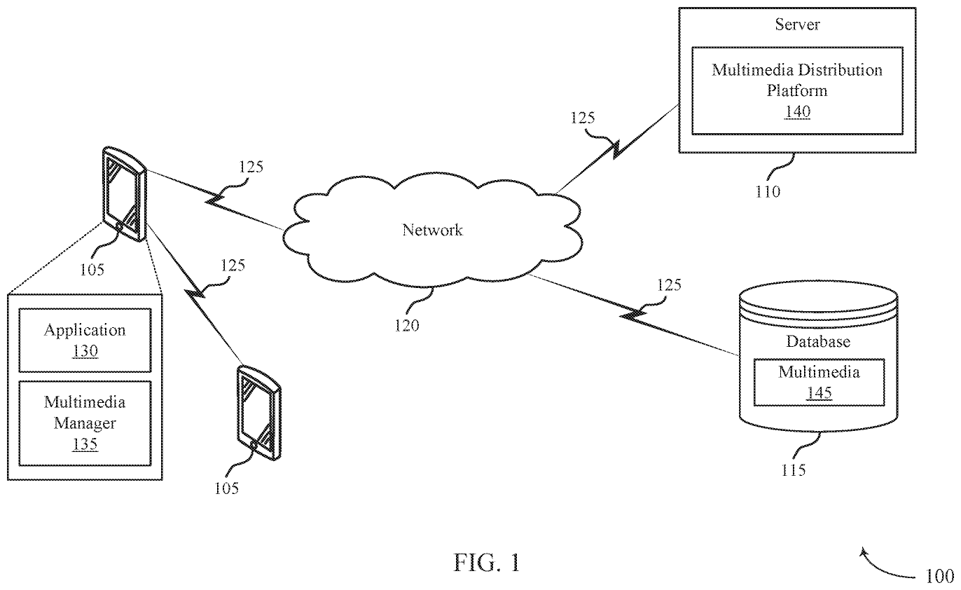

FIG. 1 illustrates a multimedia system 100 that supports glitch free audio in noisy environments in accordance with aspects of the present disclosure. The multimedia system 100 may include devices 105, a server 110, and a database 115. Although, the multimedia system 100 illustrates two devices 105, a single server 110, a single database 115, and a single network 120, the present disclosure applies to any multimedia system architecture having one or more devices 105, servers 110, databases 115, and networks 120. The devices 105, the server 110, and the database 115 may communicate with each other and exchange information that supports glitch free audio in noisy environments, such as multimedia packets (e.g., audio packets, voice packets, video packets), multimedia data, or multimedia control information, via network 120 using communications links 125. In some cases, a portion or all of the techniques described herein supporting glitch free audio in noisy environments may be performed by the devices 105 or the server 110, or both.

A device 105 may be a cellular phone, a smartphone, a personal digital assistant (PDA), a wireless communication device, a handheld device, a tablet computer, a laptop computer, a cordless phone, a display device (e.g., monitors), and/or the like that supports various types of communication and functional features related to multimedia (e.g., transmitting, receiving, broadcasting, streaming, sinking, capturing, storing, and recording multimedia data (e.g., audio packets)). A device 105 may, additionally or alternatively, be referred to by those skilled in the art as a user equipment (UE), a user device, a smartphone, a Bluetooth device, a Wi-Fi device, a mobile station, a subscriber station, a mobile unit, a subscriber unit, a wireless unit, a remote unit, a mobile device, a wireless device, a wireless communications device, a remote device, an access terminal, a mobile terminal, a wireless terminal, a remote terminal, a handset, a user agent, a mobile client, a client, and/or some other suitable terminology. In some cases, the devices 105 may also be able to communicate directly with another device (e.g., using a peer-to-peer (P2P) or device-to-device (D2D) protocol). For example, a device 105 may be able to receive from or transmit to another device 105 variety of information, such as instructions or commands (e.g., multimedia-related information).

The devices 105 may include an application 130 and a multimedia manager 135. While, the multimedia system 100 illustrates the devices 105 including both the application 130 and the multimedia manager 135, the application 130 and the multimedia manager 135 may be an optional feature for the devices 105. In some cases, the application 130 may be a multimedia-based application that can receive (e.g., download, stream, broadcast) from the server 110, database 115 or another device 105, or transmit (e.g., upload) multimedia data to the server 110, the database 115, or to another device 105 via using communications links 125.

The multimedia manager 135 may be part of a general-purpose processor, a digital signal processor (DSP), an image signal processor (ISP), a central processing unit (CPU), a graphics processing unit (GPU), a microcontroller, an application-specific integrated circuit (ASIC), a field-programmable gate array (FPGA), a discrete gate or transistor logic component, a discrete hardware component, or any combination thereof, or other programmable logic device, discrete gate or transistor logic, discrete hardware components, or any combination thereof designed to perform the functions described in the present disclosure, and/or the like. For example, the multimedia manager 135 may process multimedia (e.g., image data, video data, audio data) from and/or write multimedia data to a local memory of the device 105 or to the database 115.

The multimedia manager 135 may also be configured to provide multimedia enhancements, multimedia restoration, multimedia analysis, multimedia compression, multimedia streaming, and multimedia synthesis, among other functionality. For example, the multimedia manager 135 may perform white balancing, cropping, scaling (e.g., multimedia compression), adjusting a resolution, multimedia stitching, color processing, multimedia filtering, spatial multimedia filtering, artifact removal, frame rate adjustments, multimedia encoding, multimedia decoding, and multimedia filtering. By further example, the multimedia manager 135 may process multimedia data to support glitch free audio in noisy environments, according to the techniques described herein.

In the multimedia system 100, the devices 105 may, in some examples, support audio streaming or video streaming, or a combination thereof using packet-based protocols such as, an advanced audio distribution profile (A2DP), a logical link control and adaptation protocol (L2CAP), a Bluetooth network encapsulation protocol (BNEP), a radio frequency communication (RFCOMM) protocol, a service discovery protocol (SDP), a telephony control protocol (TCP), an audio/video control transport protocol (AVCTP), audio/video data transport protocol (AVDTP), a low energy attribute protocol (ATT), a low energy security manager protocol (SMP). In some cases, the devices 105 may experience issues with the audio streaming due to interference in the multimedia system 100. For example, a device 105 (e.g. a smartphone) streaming audio (in the form of audio packets) to another device (e.g., a Bluetooth headset) may experience a high bit error rate due to noise in the multimedia system 100. In some examples, the interference may be due to multiple active Wi-Fi links associated with the device 105 in the multimedia system 100. As a result, the device 105 may have to perform multiple retransmissions of the audio packets before an entirety of the audio packets is successfully received at the other device (e.g., the Bluetooth headset). For example, the device 105 may have to perform 10-15 retransmission for an A2DP packet. Other examples of packets may include audio packets such as, asynchronous connection-less (ACL) packets, synchronous connection-oriented (SCO) packets, low energy isochronous packets, etc.

The devices 105 may determine a probability of receiving a packet with no error over a single transmission according to Equation (1).

a=(1−p)^{L+c} (1)

L is a length of a packet in bits, N is a number of transmissions of the packet, p is a bit error rate (BER), and c is a number of CRC bits. The devices 105 may, in some examples, determine a probability of receiving a packet with at least a one bit error according to Equation (2).

ā=1−a (2)

The devices 105 may, in some examples, determine a probability of receiving a packet with no error in one or more transmissions of a number of transmissions N, according to Equation (3).

P(N)=1−ā^{N} (3)

In some cases, the devices 105 may increase an overall latency to accommodate an increased number of packet retransmissions. In some other cases, the devices 105 may support lower data rate codecs to decrease or mitigate the interference. To address the above shortcomings, the devices 105 may via the multimedia manager 135 support glitch-free multimedia streaming in the multimedia system 100. For example, the devices 105 may be configured to generate a packet, segment the packet into a set of segments (e.g., a set of audio frames), and transmit the packet including the set of segments (e.g., the set of audio frames). In other words, the devices 105 may divide an audio packet into multiple audio frames, and transmit all the audio frames in the single packet. The devices 105 may thus be configured to support, for audio applications, segmented transmission of audio packets containing multiple audio frames.

In some examples, the devices 105 may determine a probability of receiving each segment of the set of segments with no error in one or more transmissions of a number of transmissions N (attempts), according to Equation (4).

p(N)=(1−(b̅)^{N})^{M} (4)

In Equation (3), b̅ is equal to (1−b) and b is equal to (1−p)^{l+c}. M is a number of segments in a packet and l is a length of a segment in bits excluding individual CRC of length c bits (so,

$$M = \frac{L}{l} ) .$$

The devices 105 may segment the packet, excluding CRC, into M segments, and each segment is appended with a CRC. According to the above equations, based on L being 600 bytes (i.e., 4800 bits), N being 3, M being 4 (i.e., 150 bytes is equal to 1200 bits for each segment), c being 16 bits (so total segment size is 1216 bits) and BER is 10⁻⁵, the devices 105 may estimate receiving one million packets and losing about 105 packets when the packets are unsegmented. With segmenting the packets, however, the devices 105 may estimate losing about 7 packets per million.

The devices 105 may append error-detection code to one or more segments of the segmented packet, and a receiving device may confirm the presence or absence of errors in the packet based on the error-detection code. For example, the devices 105 may append a CRC to one or more segments of the segmented packet, prior to transmitting the packet via a packet-based protocol. The devices 105 may use the CRC as an error-detection code to detect errors caused to the packet by noise or interference in the multimedia system. The devices 105 may append a CRC at an ending of each segment. In some examples, the devices 105 may append the CRC at the ending of each segment via a software or hardware layer (e.g., at a digital signal processor (DSP) layer). In some other examples, the devices 105 may append the CRC at the ending of each segment via at application layer or at a firmware layer. In some examples, there may or may not be a CRC for the packet (e.g., an overall packet). In the example that the devices 105 are configured to append a CRC for an overall packet, in addition to appending separate CRCs for one or more segments of the packet, the devices 105 may be configured to process the packet even if there is an overall CRC failure.

In some examples, the described techniques may be used to configure the devices 105 (e.g., a receiver device) to verify the CRC appended to the one or more segments of the segmented packet by recording which segments have been received successfully or unsuccessfully based on decoding the CRC. In other words, at a receiver-side, the devices 105 may be check the CRC of each segment. A segment may be correct if its individual CRC passes. The devices 105 may provide feedback (e.g., a positive acknowledgement, a negative acknowledgment) indicating receipt of the packet. In some examples, the devices 105 may be configured to track, at an application layer or a software or a hardware layer, all the segments of the packet (e.g., in a A2DP packet). Once all the segments of the packet are received successfully, the application layer may provide an indication to a firmware layer that the complete packet (e.g., the full A2DP packet) is constructed.

The devices 105 (e.g., via the firmware layer) may provide a feedback (e.g., a positive acknowledgement) to a remote device (e.g., another device 105) associated with the packet transmission, even if the packet is not properly received. In some examples, the devices 105 may be configured to identify the packet for feedback, for example, via header information (e.g., a real-time transport protocol (RTP) header including a sequence number of the packet or a trail termination point (TTP)). In some examples, the devices 105 may via an application layer transmit a signal to a firmware layer indicating the header information. In some examples, the devices 105 may receive a retransmission of the packet based on the feedback. While waiting for the retransmission, the devices 105 may use any successfully received segments (e.g., audio frames) irrespective of whether all segments of the packet have been successfully received.

The devices 105 may, therefore, be configured to receive all the segments correctly from multiple transmissions. The added advantage for audio applications is that a segment (e.g., an audio frame) can be used independently (i.e., irrespective of whether other audio frames from a packet are received correctly or not). So, even if with repeated transmissions, all the segments (e.g., audio frames) of a packet are not received correctly, the devices 105 may continue to use the correctly received segment (e.g., audio frames), thereby reducing the loss of audio frames. The devices 105 may thus include features for improvements to power consumption, spectral efficiency, higher data rates and, in some examples, may promote enhanced efficiency for high reliability and low latency multimedia streaming operations in the multimedia system 100, among other benefits.

The server 110 may be a data server, a cloud server, a server associated with a multimedia subscription provider, proxy server, web server, application server, communications server, home server, mobile server, or any combination thereof. The server 110 may in some cases include a multimedia distribution platform 140. The multimedia distribution platform 140 may allow the devices 105 to discover, browse, share, and download multimedia via network 120 using communications links 125, and therefore provide a digital distribution of the multimedia from the multimedia distribution platform 140. As such, a digital distribution may be a form of delivering media content such as audio, video, images, without the use of physical media but over online delivery mediums, such as the Internet. For example, the devices 105 may upload or download multimedia-related applications for streaming, downloading, uploading, processing, enhancing, etc. multimedia (e.g., images, audio, video). The server 110 may also transmit to the devices 105 a variety of information, such as instructions or commands (e.g., multimedia-related information) to download multimedia-related applications on the device 105.

The database 115 may store a variety of information, such as instructions or commands (e.g., multimedia-related information). For example, the database 115 may store multimedia 145. The device may support glitch free audio in noisy environments associated with the multimedia 145. The device 105 may retrieve the stored data from the database 115 via the network 120 using communication links 125. In some examples, the database 115 may be a relational database (e.g., a relational database management system (RDBMS) or a Structured Query Language (SQL) database), a non-relational database, a network database, an object-oriented database, or other type of database, that stores the variety of information, such as instructions or commands (e.g., multimedia-related information).

The network 120 may provide encryption, access authorization, tracking, Internet Protocol (IP) connectivity, and other access, computation, modification, and/or functions. Examples of network 120 may include any combination of cloud networks, local area networks (LAN), wide area networks (WAN), virtual private networks (VPN), wireless networks (using 802.11, for example), cellular networks (using third generation (3G), fourth generation (4G), long-term evolved (LTE), or new radio (NR) systems (e.g., fifth generation (5G)), etc. Network 120 may include the Internet.

The communications links 125 shown in the multimedia system 100 may include uplink transmissions from the device 105 to the server 110 and the database 115, and/or downlink transmissions, from the server 110 and the database 115 to the device 105. The communication links 125 may transmit bidirectional communications and/or unidirectional communications. In some examples, the communication links 125 may be a wired connection or a wireless connection, or both. For example, the communications links 125 may include one or more connections, including but not limited to, Wi-Fi, Bluetooth, Bluetooth low-energy (BLE), cellular, Z-WAVE, 802.11, peer-to-peer, LAN, wireless local area network (WLAN), Ethernet, FireWire, fiber optic, and/or other connection types related to wireless communication systems.

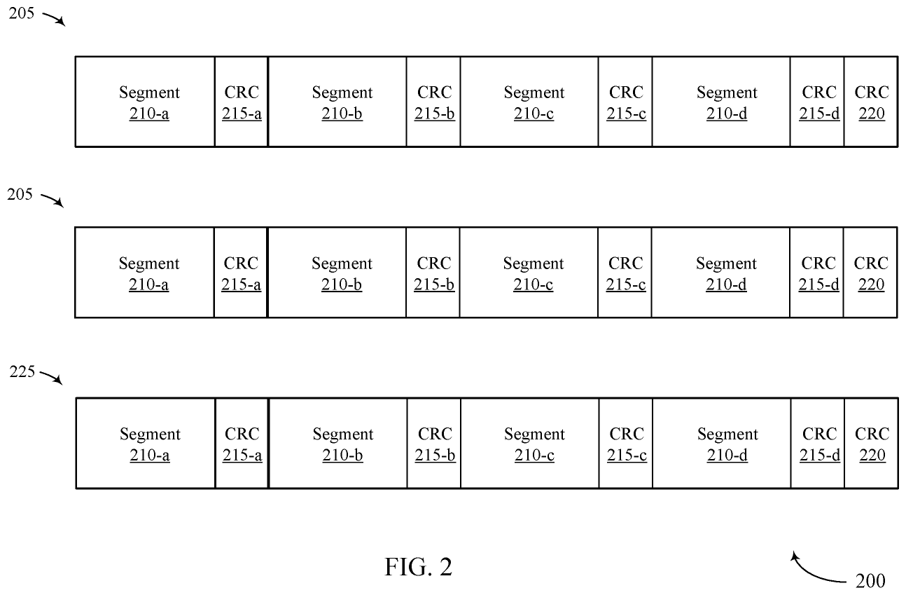

FIG. 2 illustrates an example of a communication configuration 200 that supports glitch free audio in noisy environments in accordance with aspects of the present disclosure. In some examples, the communication configuration 200 may implement aspects of the multimedia system 100, as described with reference to FIG. 1. For example, the communication configuration 200 may be based on a configuration by a device 105 or a server 110, and implemented by the device 105 or the server 110. The communication configuration 200, in the example of FIG. 2, may be illustrative of segmenting a packet for when the device 105 or the sever 110 is configured to support glitch free multimedia streaming (e.g., audio streaming, video streaming). The communication configuration 200 may thus include features for improvements to power consumption, spectral efficiency, higher data rates and, in some examples, may promote enhanced efficiency for high reliability and low latency multimedia operations the multimedia system 100, as described with reference to FIG. 1, among other benefits.

A transmitting device, for example, such as a device 105 with reference to FIG. 1 may generate a packet 205. In some examples, the packet 205 may be an audio packet or a video packet, or a combination thereof. For example, the packet 205 may be an A2DP packet for audio streaming or an advanced video distribution profile (V2DP) packet for video streaming. In some examples, the device 105 may support various packet types (i.e., A2DP packets, V2DP packets) to enable the device 105 to support video content accompanied with high-quality audio. In some examples, the device 105 may segment the packet 205 into a set of segments. For example, the device 105 may segment the packet 205 into multiple segments 210 including a first segment 210-a, a second segment 210-b, a third segment 210-c, and a fourth segment 210-d, etc. Each segment 210 may relate to one or more audio frames or video frames associated with the packet 205.

The device 105 may support use of error-detection code to detect errors caused to the packet 205 by noise or interference in a multimedia system. For example, the device 105 may support use of CRC as an error-detection code to detect errors caused to the packet 205 by noise or interference in the multimedia system. In some examples, the device 105 may append error-detection code to one or more segments 210 of the set of segments, and a receiving device may confirm the presence or absence of errors in the packet 205 based on the error-detection code. In some aspects, the device 105 may append a CRC to one or more segments 210 of the set of segments. In some other examples, the device 105 may append a CRC 215 to each segment 210 of the set of segments, where each segment 210 has a separate CRC 215 appended to it. For example, with reference to FIG. 2, the device 105 may append a first CRC 215-a to the first segment 210-a, a second CRC 215-b to the second segment 210-b, a third CRC 215-c to the third segment 210-c, and a fourth CRC 215-c to the fourth segment 210-d. The device 105 may use a same or different CRC scheme for each CRC 215. Alternatively, the device 105 may append fewer CRC. For example, the device 105 may append a CRC to exclusively a single segment 210 of the set of segments. Additionally or alternatively, the device 105 may append an additional CRC to the packet 205. For example, the device 105 may append a CRC 220 to the packet 205. In other words, the CRC 220 corresponds to the packet 205 rather than to a segment 210 associated with the packet 205. The device 105 may transmit, during a first period, the packet 205 including the set of segments to a receiving device (e.g., another device 105). The first period may correspond to time and frequency resources, for example, symbols and subcarriers.

The receiving device, for example, such as a device 105 with reference to FIG. 1 may receive, during the first period, the packet 205 including set of segments. A segment 210 of the set of segments may include an appended CRC 215, as described herein. In some examples, the device 105 may determine a corruption of one or more segments 210 of the set of segments of the packet 205. The device 105 may, in some examples, determine that each segment 210 of the set of segments of the packet 205 includes a CRC 215, and decode the CRC 215 of each segment 210 of the set of segments. For example, the device 105 may decode (or attempt to decode) the first CRC 215-a of the first segment 210-a, the second CRC 215-b of the second segment 210-b, the third CRC 215-c of the third segment 210-c, and the fourth CRC 215-c of the fourth segment 210-d. The device 105 may, thus, determine the corruption of the one or more segments 210 of the set of segments of the packet 205 based on the decoding. Additionally or alternatively, the device 105 may decode an additional CRC of the packet 205. For example, the device may decode the CRC 220 of the packet 205. Here, the device 105 may determine the corruption of one or more segments 210 of the set of segments of the packet 205 based on one or more of decoding the CRCs 215 of the segments 210 of the set of segments or decoding the additional CRC 220 of the packet 225.

The device 105 may process the one or more segments 210 of the set of segments of the packet 205 based on the corruption of the one or more segments 210. In some examples, the device 105 may determine a successful decoding of the CRCs 215 of the segments 215 of the set of segments of the packet 205. Additionally or alternatively, the device 105 may determine an unsuccessful decoding of the additional CRC 220 of the packet 205. According to the communication configuration 200, the device 105 may refrain from dropping the packet 205 based on the successful decoding of the CRCs 215 of the segment 210 of the set of segments of the packet 205 irrespective of the unsuccessful decoding of the additional CRC 220 of the packet 205. In other words, the device 105 may process the one or more segments 210 even with an overall CRC failure (e.g., unsuccessful decoding of the CRC 220).

In some examples, the device 105 may determine an unsuccessful decoding of a CRC 215 of one or more segments 210 of the set of segments of the packet 205. For example, the device 105 may be unable to successfully decode the second CRC 215-b of the second segment 210-b. The device 105 may, as a result, discard the second segment 210-b. Additionally or alternatively, the device 105 may perform a packet loss concealment operation based on the unsuccessful decoding of the second CRC 215-b. The device 105 may transmit a negative acknowledgement based on the corruption of the one or more segments 210 of the packet 205. For example, the device 105 may transmit a negative acknowledgement, to the transmitting device, based on the corruption (e.g., unsuccessful decoding) of the second CRC 215-b of the second segment 210-b.

The device 105 may continue to process the one or more segments 210 of the set of segments of the packet 205 based on the refraining. For example, the device 105 may output a representation of the segments 210 of the set of segments of the packet 205 based on the successful decoding of the CRCs 215 of the segments 210. Outputting a representation of the segments 210 may include broadcasting audio associated with the segments, or displaying video associated with the segments, or a combination thereof. In some examples, the device 105 may wait till all the segments 210 of the packet 205 have been successfully received before outputting the representation. Thus, while waiting for the retransmission, the device 105 may use any successfully received segments (e.g., audio frames) irrespective of whether all segments 210 of the packet 205 have been successfully received. The described techniques may thus include features for improvements to power consumption, spectral efficiency, higher data rates and, in some examples, may promote enhanced efficiency for high reliability and low latency multimedia streaming operations, among other benefits.

The transmitting device, for example, such as a device 105 with reference to FIG. 1 may receive the negative acknowledgement and transmit, during a second period, another packet 225 to the receiving device. The packet 225 may be equivalent or partially equivalent to the packet 205. In other words, the packet 225 may have the same set of segments of the packet 205. The receiving device, for example, such as a device 105 with reference to FIG. 1 may receive the packet 225 (e.g. a retransmission). The device 105 may determine a sequence associated with one or more of the packet 205 or the packet 225 based on header information of one or more of the packet 205 or the packet 225. The device 105 may identify the header information in an RTTP header associated with the packet 205 or the packet 225, or both.

In some examples, the device 105 may decode (or attempt to decode) the first CRC 215-a of the first segment 210-a, the second CRC 215-b of the second segment 210-b, the third CRC 215-c of the third segment 210-c, and the fourth CRC 215-c of the fourth segment 210-d associated with the packet 225. The device 105 may, thus, determine a corruption of the one or more segments 210 of the set of segments of the packet 225 based on the decoding. Additionally or alternatively, the device 105 may decode an additional CRC of the packet 225. For example, the device may decode the CRC 220 of the packet 225. Here, the device 105 may determine the corruption of one or more segments 210 of the set of segments of the packet 225 based on one or more of decoding the CRCs 215 of the segments 210 of the set of segments or decoding the additional CRC 220 of the packet 225.

The device 105 may process the one or more segments 210 of the set of segments of the packet 225 based on the corruption of the one or more segments 210. In some examples, the device 105 may determine a successful decoding of the CRCs 215 of the segments 215 of the set of segments of the packet 225. Additionally or alternatively, the device 105 may determine an unsuccessful decoding of the additional CRC 220 of the packet 225. According to the communication configuration 200, the device 105 may refrain from dropping the packet 225 based on the successful decoding of the CRCs 215 of the segment 210 of the set of segments of the packet 225 irrespective of the unsuccessful decoding of the additional CRC 220 of the packet 225. The device 105 may, therefore, process the one or more segments 210 of the set of segments of the packet 225 based on the refraining. For example, the device 105 may output a representation of the segments 210 of the set of segments of the packet 205 based on the successful decoding of the CRCs 215 of the segments 210.

In some examples, the device 105 may determine an unsuccessful decoding of a CRC 215 of one or more segments 210 of the set of segments of the packet 225. For example, the device 105 may be unable to successfully decode the third CRC 215-c of the third segment 210-c of the packet 225. The device 105 may, as a result, discard the third segment 210-c. Additionally or alternatively, the device 105 may perform a packet loss concealment operation based on the unsuccessful decoding of the third CRC 215-c. The device 105 may aggregate the one or more segments 210 of the set of segments of the packet 205 and the one or more of the segments 210 of the set of segments of the packet 205 received in the packet 225, and determine whether all the segments 210 of the packet 205 have been successfully received. In some examples, the aggregating occurs at an upper layer of the device 105. In some aspects, the device 105 may aggregate the one or more segments 210 at a controller of the device 105 (e.g., at a multimedia manager 135 or a processor 740 as described herein). If the device 105 determines that some segments 210 of the packet 205 have not been received, the device 105 may transmit another negative acknowledgement based on the corruption of the one or more segments 210 of the packet 225. For example, the device 105 may transmit a negative acknowledgement, to the transmitting device, based on the corruption (e.g., unsuccessful decoding) of the third CRC 215-c of the third segment 210-c. Otherwise, the device 105 may output a representation of all the segments 210 of the packet 205. In other words, the device may combine the successfully decoded segments 210 associated with the packet 205 and the successfully decoded segments 210 associated with the packet 225 to construct all the segments or complete a packet when individual packets are not successfully received at the device 105.

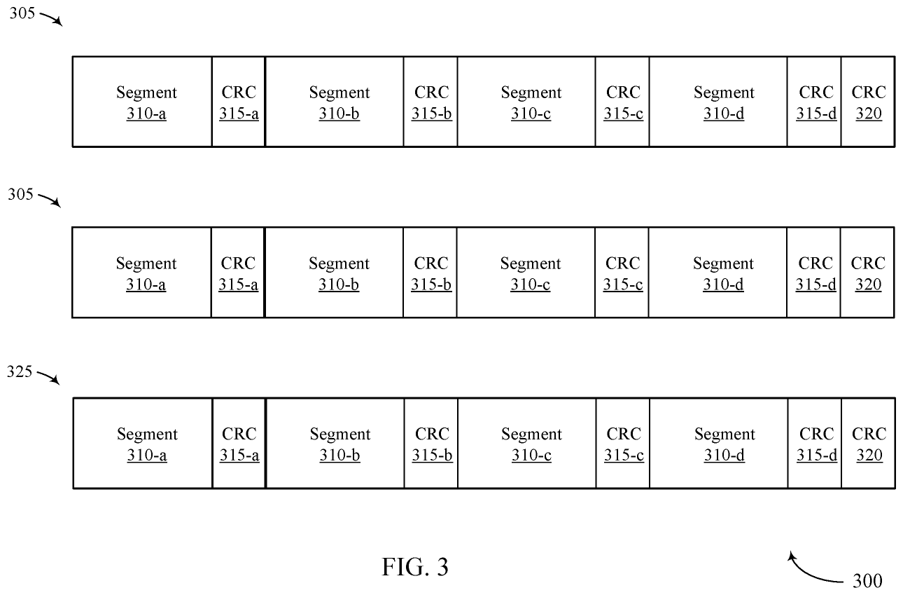

FIG. 3 illustrates an example of a communication configuration 300 that supports glitch free audio in noisy environments in accordance with aspects of the present disclosure. In some examples, the communication configuration 300 may implement aspects of the multimedia system 100, as described with reference to FIG. 1. For example, the communication configuration 300 may be based on a configuration by a device 105 or a server 110, and implemented by the device 105 or the server 110. The communication configuration 300, in the example of FIG. 2, may be illustrative of segmenting a packet for when the device 105 or the sever 110 is configured to support glitch free multimedia streaming (e.g., audio streaming, video streaming). The communication configuration 300 may thus include features for improvements to power consumption, spectral efficiency, higher data rates and, in some examples, may promote enhanced efficiency for high reliability and low latency multimedia operations the multimedia system 100, as described with reference to FIG. 1, among other benefits.

A transmitting device, for example, such as a device 105 with reference to FIG. 1 may generate a packet 305. In some examples, the packet 305 may be an audio packet or a video packet, or a combination thereof. For example, the packet 305 may be an A2DP packet for audio streaming or a V2DP packet for video streaming. In some examples, the device 105 may support various packet types (i.e., A2DP packets, V2DP packets) to enable the device 105 to support video content accompanied with audio. In some examples, the device 105 may segment the packet 305 into a set of segments. For example, the device 105 may segment the packet 305 into multiple segments 310 including a first segment 310-a, a second segment 310-b, a third segment 310-c, and a fourth segment 310-d, etc. Each segment 310 may relate to one or more audio frames or video frames associated with the packet 305.

The device 105 may support use of error-detection code to detect errors caused to the packet 205 by noise or interference in a multimedia system. For example, the device 105 may support use of CRC as an error-detection code to detect errors caused to the packet 305 by noise or interference in the multimedia system. In some examples, the device 105 may append error-detection code to one or more segments 310 of the set of segments, and a receiving device may confirm the presence or absence of errors in the packet 305 based on the error-detection code. In some aspects, the device 105 may append a CRC to one or more segments 310 of the set of segments. In some other examples, the device 105 may append a CRC 315 to each segment 310 of the set of segments, where each segment 310 has a separate CRC 315 appended to it. For example, with reference to FIG. 3, the device 105 may append a first CRC 315-a to the first segment 310-a, a second CRC 315-b to the second segment 310-b, a third CRC 315-c to the third segment 310-c, and a fourth CRC 315-c to the fourth segment 310-d. The device 105 may use a same or different CRC scheme for each CRC 315. Alternatively, the device 105 may append fewer CRC. For example, the device 105 may append a CRC to a single segment 310 of the set of segments. Additionally or alternatively, the device 105 may append an additional CRC to the packet 305. For example, the device 105 may append a CRC 320 to the packet 305. In other words, the CRC 320 corresponds to the overall packet 305. The device 105 may transmit, during a first period, the packet 305 including the set of segments to a receiving device (e.g., another device 105).

The receiving device, for example, such as a device 105 with reference to FIG. 1 may receive, during the first period, the packet 305 including set of segments. A segment 310 of the set of segments may include an appended CRC 315, as described herein. In some examples, the device 105 may determine a corruption of one or more segments 310 of the set of segments of the packet 305. The device 105 may, in some examples, determine that each segment 310 of the set of segments of the packet 305 includes a CRC 315, and decode the CRC 315 of each segment 310 of the set of segments. For example, the device 105 may decode (or attempt to decode) the first CRC 315-a of the first segment 310-a, the second CRC 315-b of the second segment 310-b, the third CRC 315-c of the third segment 310-c, and the fourth CRC 315-c of the fourth segment 310-d. The device 105 may, thus, determine the corruption of the one or more segments 310 of the set of segments of the packet 305 based on the decoding. Additionally or alternatively, the device 105 may decode an additional CRC of the packet 305. For example, the device may decode the CRC 320 of the packet 305. Here, the device 105 may determine the corruption of one or more segments 310 of the set of segments of the packet 305 based on one or more of decoding the CRCs 315 of the segments 310 of the set of segments or decoding the additional CRC 320 of the packet 325.

The device 105 may process the one or more segments 310 of the set of segments of the packet 305 based on the corruption of the one or more segments 310. In some examples, the device 105 may determine a successful decoding of the CRCs 315 of the segments 310 of the set of segments of the packet 305. Additionally or alternatively, the device 105 may determine an unsuccessful decoding of the additional CRC 320 of the packet 305. According to the communication configuration 300, the device 105 may refrain from dropping the packet 305 based on the successful decoding of the CRCs 315 of the segment 310 of the set of segments of the packet 305 irrespective of the unsuccessful decoding of the additional CRC 320 of the packet 305. In other words, the device 105 may process the one or more segments 310 even with an overall CRC failure (e.g., unsuccessful decoding of the CRC 320).

The device 105 may, in some examples, determine an unsuccessful decoding of a CRC 315 of one or more segments 310 of the set of segments of the packet 305. For example, the device 105 may be unable to successfully decode the second CRC 315-b of the second segment 310-b. The device 105 may, as a result, discard the second segment 310-b. Additionally or alternatively, the device 105 may perform a packet loss concealment operation based on the unsuccessful decoding of the second CRC 315-b. The device 105 may transmit a negative acknowledgement based on the corruption of the one or more segments 310 of the packet 305. For example, the device 105 may transmit a negative acknowledgement, to the transmitting device, based on the corruption (e.g., unsuccessful decoding) of the second CRC 315-b of the second segment 310-b.

In some examples, the device 105 may continue to process the one or more segments 310 of the set of segments of the packet 305 based on the refraining. For example, the device 105 may output a representation of the segments 310 of the set of segments of the packet 305 based on the successful decoding of the CRCs 315 of the segments 310. Outputting a representation of the segments 310 may include broadcasting audio associated with the segments, or displaying video associated with the segments, or a combination thereof. In some examples, the device 105 may delay outputting the representation until all the segments 310 of the packet 305 have been successfully received before outputting the representation. Thus, while waiting for the retransmission, the device 105 may use any successfully received segments (e.g., audio frames) irrespective of whether all segments 310 of the packet 305 have been successfully received. The described techniques may thus include features for improvements to power consumption, spectral efficiency, higher data rates and, in some examples, may promote enhanced efficiency for high reliability and low latency multimedia streaming operations, among other benefits.

The transmitting device, for example, such as a device 105 with reference to FIG. 1 may receive the negative acknowledgement and transmit, during a second period, another packet 325 to the receiving device. The packet 325 may be equivalent or partially equivalent to the packet 305. In other words, the packet 325 may have the same set of segments of the packet 305. The receiving device, for example, such as a device 105 with reference to FIG. 1 may receive the packet 325 (e.g. a retransmission). The device 105 may determine a sequence associated with one or more of the packet 305 or the packet 325 based on header information of one or more of the packet 305 or the packet 325. The device 105 may identify the header information in an RTTP header associated with the packet 305 or the packet 325, or both.

In some examples, the device 105 may decode (or attempt to decode) the first CRC 315-a of the first segment 310-a, the second CRC 315-b of the second segment 310-b, the third CRC 315-c of the third segment 310-c, and the fourth CRC 315-c of the fourth segment 310-d associated with the packet 325. The device 105 may, thus, determine a corruption of the one or more segments 310 of the set of segments of the packet 325 based on the decoding. Additionally or alternatively, the device 105 may decode an additional CRC of the packet 325. For example, the device may decode the CRC 320 of the packet 325. Here, the device 105 may determine the corruption of one or more segments 310 of the set of segments of the packet 325 based on one or more of decoding the CRCs 315 of the segments 310 of the set of segments or decoding the additional CRC 320 of the packet 325.

The device 105 may process the one or more segments 310 of the set of segments of the packet 325 based on the corruption of the one or more segments 310. In some examples, the device 105 may determine a successful decoding of the CRCs 315 of the segments 310 of the set of segments of the packet 325. Additionally or alternatively, the device 105 may determine an unsuccessful decoding of the additional CRC 320 of the packet 325. According to the communication configuration 300, the device 105 may refrain from dropping the packet 325 based on the successful decoding of the CRCs 315 of the segment 310 of the set of segments of the packet 325 irrespective of the unsuccessful decoding of the additional CRC 320 of the packet 325. The device 105 may, therefore, process the one or more segments 310 of the set of segments of the packet 325 based on the refraining. For example, the device 105 may output a representation of the segments 310 of the set of segments of the packet 305 based on the successful decoding of the CRCs 315 of the segments 310. In some examples, the device 105 may determine an unsuccessful decoding of a CRC 315 of one or more segments 310 of the set of segments of the packet 325. For example, the device 105 may be unable to successfully decode the second CRC 315-b of the second segment 310-b of the packet 325. The device 105 may, as a result, discard the second segment 310-b. Additionally or alternatively, the device 105 may perform a packet loss concealment operation based on the unsuccessful decoding of the second CRC 315-b.

The device 105 may aggregate the one or more segments 310 of the set of segments of the packet 305 and the one or more of the segments 310 of the set of segments of the packet 305 received in the packet 325, and determine whether all the segments 310 of the packet 305 have been successfully received. In some examples, the aggregating occurs at an upper layer of the device 105. In some aspects, the device 105 may aggregate the one or more segments 210 at a controller of the device 105 (e.g., at a multimedia manager 135 or a processor 740 as described herein). If the device 105 determines that some segments 310 of the packet 305 have not been received, the device 105 may transmit another negative acknowledgement based on the corruption of the one or more segments 310 of the packet 325. For example, the device 105 may transmit a negative acknowledgement, to the transmitting device, based on the corruption (e.g., unsuccessful decoding) of the second CRC 315-b of the second segment 310-b. Otherwise, the device 105 may output a representation of all the segments 310 of the packet 305. In other words, the device may combine the successfully decoded segments 310 associated with the packet 305 and the successfully decoded segments 310 associated with the packet 325 to construct all the segments when individual segments or packets are not successfully received at the device 105.

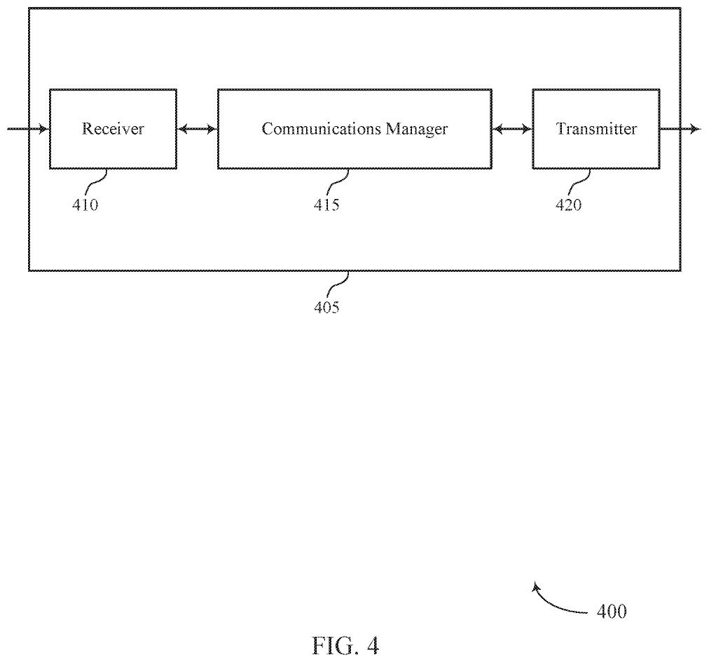

FIG. 4 shows a block diagram 400 of a device 405 that supports glitch free audio in noisy environments in accordance with aspects of the present disclosure. The device 405 may be an example of aspects of a device as described herein. The device 405 may include a receiver 410, a communications manager 415, and a transmitter 420. The device 405 may also include a processor. Each of these components may be in communication with one another (e.g., via one or more buses).

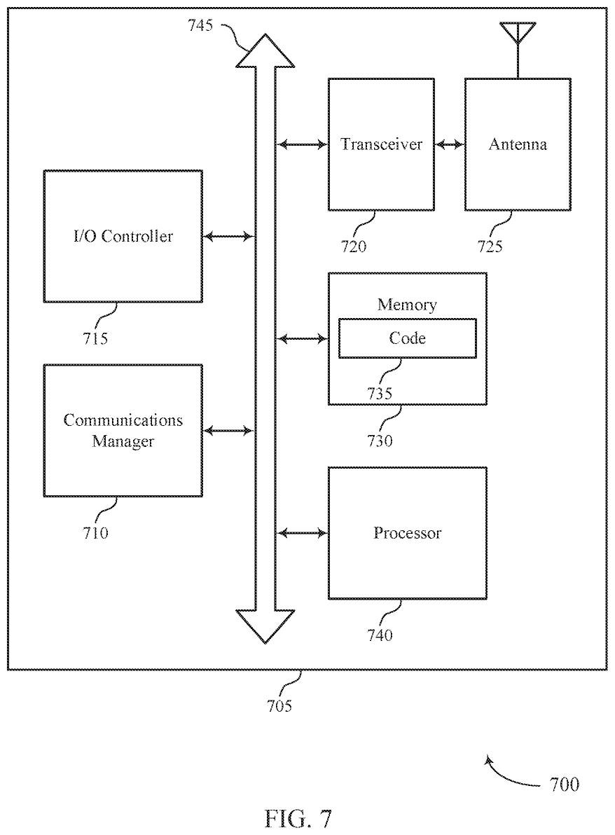

The receiver 410 may receive information such as packets, user data, or control information associated with various information channels (e.g., control channels, data channels, and information related to glitch free audio in noisy environments, etc.). Information may be passed on to other components of the device 405. The receiver 410 may be an example of aspects of the transceiver 720 described with reference to FIG. 7. The receiver 410 may utilize a single antenna or a set of antennas.

The communications manager 415 may be an example of aspects of the multimedia manager 135 as described herein. The communications manager 415 may receive, during a first period, a first packet including a set of segments, where a segment of the set of segments includes a CRC, receive, during a second period, a second packet based on the corruption of the one or more segments of the set of segments of the first packet, the second packet including one or more of the segments of the set of segments of the first packet, determine a corruption of one or more segments of the set of segments of the first packet based on the receiving, process the one or more segments of the set of segments of the first packet based on the corruption of the one or more segments of the first packet, process the one or more segments of the set of segments of the first packet received in the second packet, and transmit a positive acknowledgment indicating a reception of all segments of the set of segments based on the first packet and the second packet.

The communications manager 415 may also generate a packet, transmit, during a first period, the packet including the set of segments to a device, segment the packet into a set of segments, and append a CRC to one or more segments of the set of segments based on segmenting the packet into the set of segments. The communications manager 415 may be an example of aspects of the communications manager 710 described herein.

The communications manager 415, or its sub-components, may be implemented in hardware, code (e.g., software or firmware) executed by a processor, or any combination thereof. If implemented in code executed by a processor, the functions of the communications manager 415, or its sub-components may be executed by a general-purpose processor, a DSP, an application-specific integrated circuit (ASIC), a FPGA or other programmable logic device, discrete gate or transistor logic, discrete hardware components, or any combination thereof designed to perform the functions described in the present disclosure.

The communications manager 415, or its sub-components, may be physically located at various positions, including being distributed such that portions of functions are implemented at different physical locations by one or more physical components. In some examples, the communications manager 415, or its sub-components, may be a separate and distinct component in accordance with various aspects of the present disclosure. In some examples, the communications manager 415, or its sub-components, may be combined with one or more other hardware components, including but not limited to an input/output (I/O) component, a transceiver, a network server, another computing device, one or more other components described in the present disclosure, or a combination thereof in accordance with various aspects of the present disclosure.

The transmitter 420 may transmit signals generated by other components of the device 405. In some examples, the transmitter 420 may be collocated with a receiver 410 in a transceiver module. For example, the transmitter 420 may be an example of aspects of the transceiver 720 described with reference to FIG. 7. The transmitter 420 may utilize a single antenna or a set of antennas.

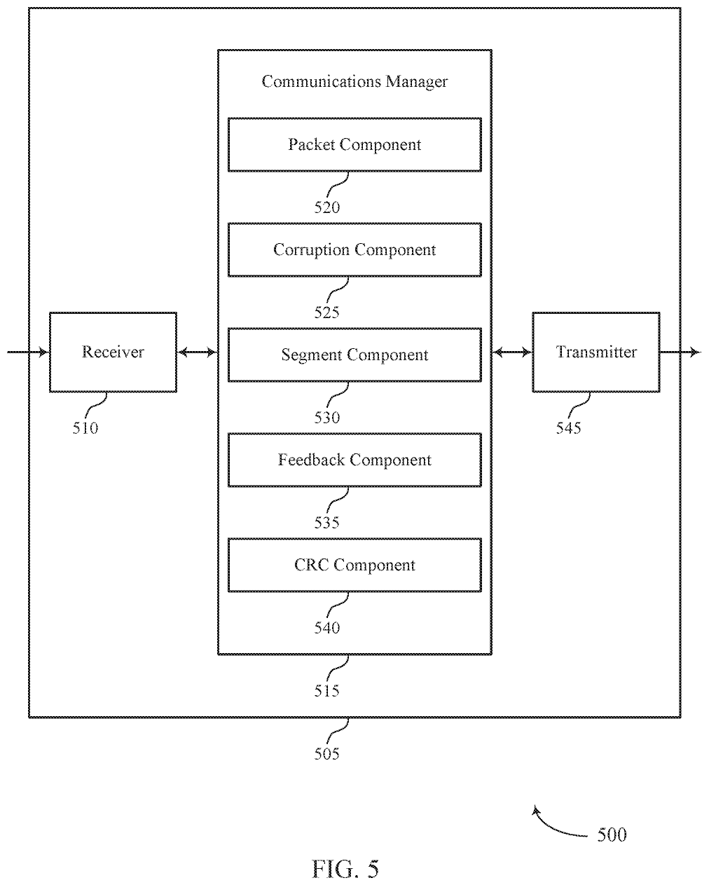

FIG. 5 shows a block diagram 500 of a device 505 that supports glitch free audio in noisy environments in accordance with aspects of the present disclosure. The device 505 may be an example of aspects of a device 405 or a device 115 as described herein. The device 505 may include a receiver 510, a communications manager 515, and a transmitter 545. The device 505 may also include a processor. Each of these components may be in communication with one another (e.g., via one or more buses).

The receiver 510 may receive information such as packets, user data, or control information associated with various information channels (e.g., control channels, data channels, and information related to glitch free audio in noisy environments, etc.). Information may be passed on to other components of the device 505. The receiver 510 may be an example of aspects of the transceiver 720 described with reference to FIG. 7. The receiver 510 may utilize a single antenna or a set of antennas.

The communications manager 515 may be an example of aspects of the communications manager 415 as described herein. The communications manager 515 may include a packet component 520, a corruption component 525, a segment component 530, a feedback component 535, and a CRC component 540. The communications manager 515 may be an example of aspects of the communications manager 710 described herein.

The packet component 520 may receive, during a first period, a first packet including a set of segments, where a segment of the set of segments includes a CRC and receive, during a second period, a second packet based on a corruption of one or more segments of the set of segments of the first packet, the second packet including one or more of the segments of the set of segments of the first packet. The corruption component 525 may determine the corruption of the one or more segments of the set of segments of the first packet based on the receiving. The segment component 530 may process the one or more segments of the set of segments of the first packet based on the corruption of the one or more segments of the first packet and process the one or more segments of the set of segments of the first packet received in the second packet. The feedback component 535 may transmit a positive acknowledgment indicating a reception of all segments of the set of segments based on the first packet and the second packet.

The packet component 520 may generate a packet and transmit, during a first period, the packet including the set of segments to a device. The segment component 530 may segment the packet into a set of segments. The CRC component 540 may append a CRC to one or more segments of the set of segments based on segmenting the packet into the set of segments.

The transmitter 545 may transmit signals generated by other components of the device 505. In some examples, the transmitter 545 may be collocated with a receiver 510 in a transceiver module. For example, the transmitter 545 may be an example of aspects of the transceiver 720 described with reference to FIG. 7. The transmitter 545 may utilize a single antenna or a set of antennas.

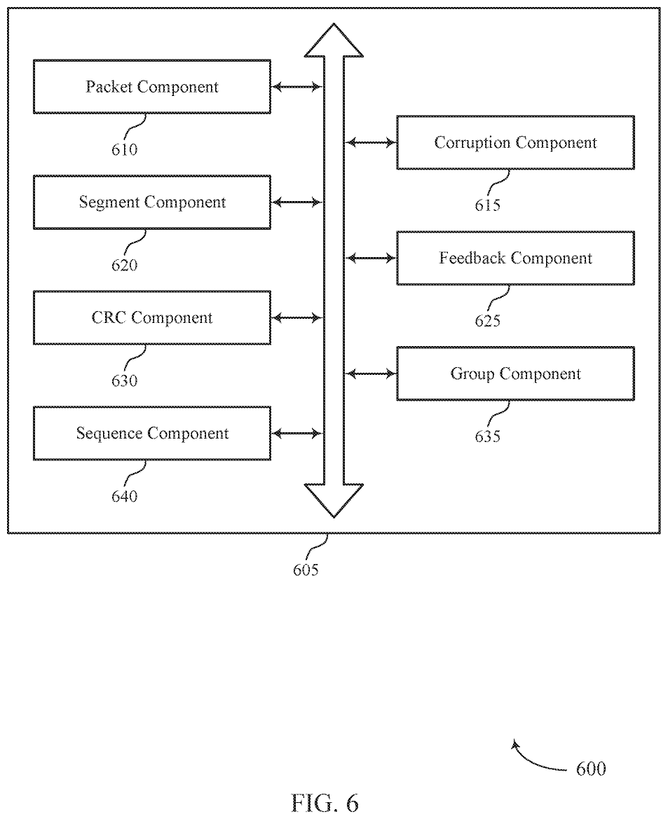

FIG. 6 shows a block diagram 600 of a communications manager 605 that supports glitch free audio in noisy environments in accordance with aspects of the present disclosure. The communications manager 605 may be an example of aspects of a communications manager 415, a communications manager 515, or a communications manager 710 described herein. The communications manager 605 may include a packet component 610, a corruption component 615, a segment component 620, a feedback component 625, a CRC component 630, a group component 635, and a sequence component 640. Each of these modules may communicate, directly or indirectly, with one another (e.g., via one or more buses).

The packet component 610 may receive, during a first period, a first packet including a set of segments, where a segment of the set of segments includes a CRC. In some examples, the packet component 610 may receive, during a second period, a second packet based on the corruption of the one or more segments of the set of segments of the first packet, the second packet including one or more of the segments of the set of segments of the first packet. In some cases, one or more of the first packet or the second packet includes an advanced audio distribution profile packet. In some cases, one or more of the first packet or the second packet includes an audio packet or a video packet, or a combination thereof.

In some examples, the packet component 610 may generate a packet. In some examples, the packet component 610 may transmit, during a first period, the packet including the set of segments to a device. In some examples, the packet component 610 may transmit, during a second period, a second packet to the device, the second packet including the set of segments transmitted in the packet, where transmitting the second packet is based on receiving a negative acknowledgement. In some examples, the packet component 610 may refrain from transmitting a third packet including one or more of the segments of the set of segments of the first packet or the second packet.

The corruption component 615 may determine a corruption of one or more segments of the set of segments of the first packet based on the receiving. The segment component 620 may process the one or more segments of the set of segments of the first packet based on the corruption of the one or more segments of the first packet. In some examples, the segment component 620 may process the one or more segments of the set of segments of the first packet received in the second packet. In some examples, the segment component 620 may segment the packet into a set of segments. In some examples, the segment component 620 may output a representation of the segment of the set of segments of the first packet based on the successful decoding of the CRC of the segment. In some cases, each segment of the set of segments includes a CRC. In some cases, each segment of the set of segments includes a separate CRC.

The feedback component 625 may transmit a positive acknowledgment indicating a reception of all segments of the set of segments based on the first packet and the second packet. In some examples, the feedback component 625 may receive a negative acknowledgement associated with transmitting the packet. In some examples, the feedback component 625 may receive a positive acknowledgment indicating a reception of all segments of the set of segments based on the first packet and the second packet. In some cases, the feedback component 625 may transmit a negative acknowledgement based on the corruption of the one or more segments of the first packet, where receiving the second packet includes receiving, during the second period, the second packet based on the negative acknowledgement.

The CRC component 630 may append a CRC to one or more segments of the set of segments based on segmenting the packet into the set of segments. In some examples, the CRC component 630 may determine that each segment of the set of segments of the first packet includes a CRC. In some examples, the CRC component 630 may decode the CRC of each segment of the set of segments, where determining the corruption of the one or more segments of the set of segments of the first packet is based on the decoding. In some examples, the CRC component 630 may decode the CRC of the segment of the set of segments of the first packet. In some examples, the CRC component 630 may decode an additional CRC of the first packet, where determining the corruption of one or more segments of the set of segments of the first packet is based on one or more of decoding the CRC of the segment of the set of segments or decoding the additional CRC of the first packet.

In some examples, the CRC component 630 may determine a successful decoding of the CRC of the segment of the set of segments of the first packet. In some examples, the CRC component 630 may determine an unsuccessful decoding of an additional CRC of the first packet. In some examples, the CRC component 630 may refrain from dropping the first packet based on the successful decoding of the CRC of the segment of the set of segments of the first packet, where processing the one or more segments of the set of segments of the first packet is based on the refraining. In some examples, the CRC component 630 may determine an unsuccessful decoding of a second CRC of a second segment of the set of segments of the first packet. In some examples, the CRC component 630 may discard the second segment based on the unsuccessful decoding of a second CRC. In some examples, the CRC component 630 may perform a packet loss concealment operation based on the unsuccessful decoding of a second CRC. In some examples, the CRC component 630 may append an additional CRC to the first packet. The group component 635 may aggregate the one or more segments of the set of segments of the first packet and the one or more of the segments of the set of segments of the first packet received in the second packet, where the aggregating occurs at an upper layer of the device.

The sequence component 640 may determine a sequence associated with one or more of the first packet or the second packet based on header information of one or more of the first packet or the second packet, where transmitting the positive acknowledgement is based on the sequence associated with one or more of the first packet or the second packet. In some examples, the sequence component 640 may identify the header information in a real-time transport protocol header associated with one or more of the first packet or the second packet.

FIG. 7 shows a diagram of a system 700 including a device 705 that supports glitch free audio in noisy environments in accordance with aspects of the present disclosure. The device 705 may be an example of or include the components of device 405, device 505, or a device as described herein. The device 705 may include components for bi-directional voice and data communications including components for transmitting and receiving communications, including a communications manager 710, an I/O controller 715, a transceiver 720, an antenna 725, memory 730, a processor 740, and a coding manager 750. These components may be in electronic communication via one or more buses (e.g., bus 745).

The communications manager 710 may receive, during a first period, a first packet including a set of segments, where a segment of the set of segments includes a CRC, receive, during a second period, a second packet based on the corruption of the one or more segments of the set of segments of the first packet, the second packet including one or more of the segments of the set of segments of the first packet, determine a corruption of one or more segments of the set of segments of the first packet based on the receiving, process the one or more segments of the set of segments of the first packet based on the corruption of the one or more segments of the first packet, process the one or more segments of the set of segments of the first packet received in the second packet, and transmit a positive acknowledgment indicating a reception of all segments of the set of segments based on the first packet and the second packet. The communications manager 710 may also generate a packet, transmit, during a first period, the packet including the set of segments to a device, segment the packet into a set of segments, and append a CRC to one or more segments of the set of segments based on segmenting the packet into the set of segments. The communications manager 710 and/or one or more components of the communications manager 710 may perform and/or be a means for performing, either alone or in combination with other elements, one or more operations for supports glitch free audio in noisy environments.

The I/O controller 715 may manage input and output signals for the device 705. The I/O controller 715 may also manage peripherals not integrated into the device 705. In some cases, the I/O controller 715 may represent a physical connection or port to an external peripheral. In some cases, the I/O controller 715 may utilize an operating system such as iOS®, ANDROID), MS-DOS®, MS-WINDOWS®, OS/2®, UNIX®, LINUX®, or another known operating system. In other cases, the I/O controller 715 may represent or interact with a modem, a keyboard, a mouse, a touchscreen, or a similar device. In some cases, the I/O controller 715 may be implemented as part of a processor. In some cases, a user may interact with the device 705 via the I/O controller 715 or via hardware components controlled by the I/O controller 715.

The transceiver 720 may communicate bi-directionally, via one or more antennas, wired, or wireless links as described above. For example, the transceiver 720 may represent a wireless transceiver and may communicate bi-directionally with another wireless transceiver. The transceiver 720 may also include a modem to modulate the packets and provide the modulated packets to the antennas for transmission, and to demodulate packets received from the antennas. In some cases, the device 705 may include a single antenna 725. However, in some cases, the device 705 may have more than one antenna 725, which may be capable of concurrently transmitting or receiving multiple wireless transmissions.

The memory 730 may include RAM and ROM. The memory 730 may store computer-readable, computer-executable code 735 including instructions that, when executed, cause the processor to perform various functions described herein. In some cases, the memory 730 may contain, among other things, a BIOS which may control basic hardware or software operation such as the interaction with peripheral components or devices.

The code 735 may include instructions to implement aspects of the present disclosure, including instructions to support wireless communications. The code 735 may be stored in a non-transitory computer-readable medium such as system memory or other type of memory. In some cases, the code 735 may not be directly executable by the processor 740 but may cause a computer (e.g., when compiled and executed) to perform functions described herein.

The processor 740 may include an intelligent hardware device, (e.g., a general-purpose processor, a DSP, a CPU, a microcontroller, an ASIC, an FPGA, a programmable logic device, a discrete gate or transistor logic component, a discrete hardware component, or any combination thereof). In some cases, the processor 740 may be configured to operate a memory array using a memory controller. In other cases, a memory controller may be integrated into the processor 740. The processor 740 may be configured to execute computer-readable instructions stored in a memory (e.g., the memory 730) to cause the device 705 to perform various functions (e.g., functions or tasks supporting glitch free audio in noisy environments).

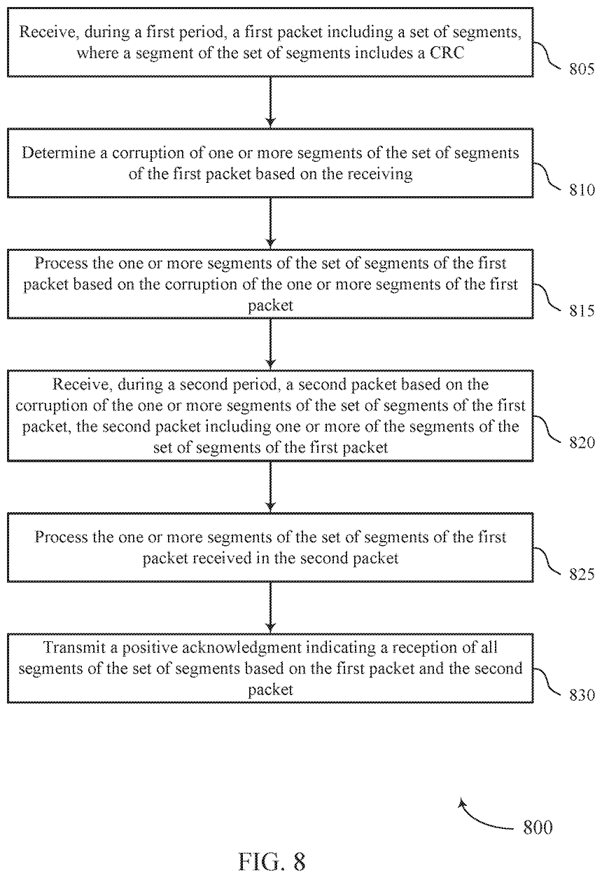

FIG. 8 shows a flowchart illustrating a method 800 that supports glitch free audio in noisy environments in accordance with aspects of the present disclosure. The operations of method 800 may be implemented by a device or its components as described herein. For example, the operations of method 800 may be performed by a communications manager as described with reference to FIGS. 4 through 7. In some examples, a device may execute a set of instructions to control the functional elements of the device to perform the functions described below. Additionally or alternatively, a device may perform aspects of the functions described below using special-purpose hardware.

At 805, the device may receive, during a first period, a first packet including a set of segments, where a segment of the set of segments includes a CRC. The operations of 805 may be performed according to the methods described herein. In some examples, aspects of the operations of 805 may be performed by a packet component as described with reference to FIGS. 4 through 7.

At 810, the device may determine a corruption of one or more segments of the set of segments of the first packet based on the receiving. The operations of 810 may be performed according to the methods described herein. In some examples, aspects of the operations of 810 may be performed by a corruption component as described with reference to FIGS. 4 through 7.

At 815, the device may process the one or more segments of the set of segments of the first packet based on the corruption of the one or more segments of the first packet. The operations of 815 may be performed according to the methods described herein. In some examples, aspects of the operations of 815 may be performed by a segment component as described with reference to FIGS. 4 through 7.

At 820, the device may receive, during a second period, a second packet based on the corruption of the one or more segments of the set of segments of the first packet, the second packet including one or more of the segments of the set of segments of the first packet. The operations of 820 may be performed according to the methods described herein. In some examples, aspects of the operations of 820 may be performed by a packet component as described with reference to FIGS. 4 through 7.

At 825, the device may process the one or more segments of the set of segments of the first packet received in the second packet. The operations of 825 may be performed according to the methods described herein. In some examples, aspects of the operations of 825 may be performed by a segment component as described with reference to FIGS. 4 through 7.

At 830, the device may transmit a positive acknowledgment indicating a reception of all segments of the set of segments based on the first packet and the second packet. The operations of 830 may be performed according to the methods described herein. In some examples, aspects of the operations of 830 may be performed by a feedback component as described with reference to FIGS. 4 through 7.

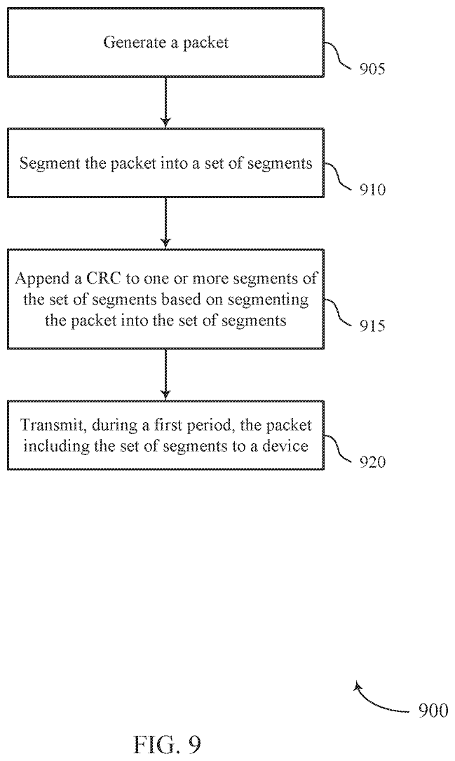

FIG. 9 shows a flowchart illustrating a method 900 that supports glitch free audio in noisy environments in accordance with aspects of the present disclosure. The operations of method 900 may be implemented by a device or its components as described herein. For example, the operations of method 900 may be performed by a communications manager as described with reference to FIGS. 4 through 7. In some examples, a device may execute a set of instructions to control the functional elements of the device to perform the functions described below. Additionally or alternatively, a device may perform aspects of the functions described below using special-purpose hardware.

At 905, the device may generate a packet. The operations of 905 may be performed according to the methods described herein. In some examples, aspects of the operations of 905 may be performed by a packet component as described with reference to FIGS. 4 through 7.

At 910, the device may segment the packet into a set of segments. The operations of 910 may be performed according to the methods described herein. In some examples, aspects of the operations of 910 may be performed by a segment component as described with reference to FIGS. 4 through 7.

At 915, the device may append a CRC to one or more segments of the set of segments based on segmenting the packet into the set of segments. The operations of 915 may be performed according to the methods described herein. In some examples, aspects of the operations of 915 may be performed by a CRC component as described with reference to FIGS. 4 through 7.

At 920, the device may transmit, during a first period, the packet including the set of segments to a device. The operations of 920 may be performed according to the methods described herein. In some examples, aspects of the operations of 920 may be performed by a packet component as described with reference to FIGS. 4 through 7.

It should be noted that the methods described herein describe possible implementations, and that the operations and the steps may be rearranged or otherwise modified and that other implementations are possible. Further, aspects from two or more of the methods may be combined.

Although aspects of an LTE, LTE-A, LTE-A Pro, or NR system may be described for purposes of example, and LTE, LTE-A, LTE-A Pro, or NR terminology may be used in much of the description, the techniques described herein are applicable beyond LTE, LTE-A, LTE-A Pro, or NR networks. For example, the described techniques may be applicable to various other wireless communications systems such as Ultra Mobile Broadband (UMB), Institute of Electrical and Electronics Engineers (IEEE) 802.11 (Wi-Fi), IEEE 802.16 (WiMAX), IEEE 802.20, Flash-OFDM, as well as other systems and radio technologies not explicitly mentioned herein.

Information and signals described herein may be represented using any of a variety of different technologies and techniques. For example, data, instructions, commands, information, signals, bits, symbols, and chips that may be referenced throughout the description may be represented by voltages, currents, electromagnetic waves, magnetic fields or particles, optical fields or particles, or any combination thereof.

The various illustrative blocks and components described in connection with the disclosure herein may be implemented or performed with a general-purpose processor, a DSP, an ASIC, a CPU, an FPGA or other programmable logic device, discrete gate or transistor logic, discrete hardware components, or any combination thereof designed to perform the functions described herein. A general-purpose processor may be a microprocessor, but in the alternative, the processor may be any processor, controller, microcontroller, or state machine. A processor may also be implemented as a combination of computing devices (e.g., a combination of a DSP and a microprocessor, multiple microprocessors, one or more microprocessors in conjunction with a DSP core, or any other such configuration).

The functions described herein may be implemented in hardware, software executed by a processor, firmware, or any combination thereof. If implemented in software executed by a processor, the functions may be stored on or transmitted over as one or more instructions or code on a computer-readable medium. Other examples and implementations are within the scope of the disclosure and appended claims. For example, due to the nature of software, functions described herein may be implemented using software executed by a processor, hardware, firmware, hardwiring, or combinations of any of these. Features implementing functions may also be physically located at various positions, including being distributed such that portions of functions are implemented at different physical locations.

Computer-readable media includes both non-transitory computer storage media and communication media including any medium that facilitates transfer of a computer program from one place to another. A non-transitory storage medium may be any available medium that may be accessed by a general-purpose or special purpose computer. By way of example, and not limitation, non-transitory computer-readable media may include random-access memory (RAM), read-only memory (ROM), electrically erasable programmable ROM (EEPROM), flash memory, compact disk (CD) ROM or other optical disk storage, magnetic disk storage or other magnetic storage devices, or any other non-transitory medium that may be used to carry or store desired program code means in the form of instructions or data structures and that may be accessed by a general-purpose or special-purpose computer, or a general-purpose or special-purpose processor. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of computer-readable medium. Disk and disc, as used herein, include CD, laser disc, optical disc, digital versatile disc (DVD), floppy disk and Blu-ray disc where disks usually reproduce data magnetically, while discs reproduce data optically with lasers. Combinations of the above are also included within the scope of computer-readable media.

As used herein, including in the claims, “or” as used in a list of items (e.g., a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an example step that is described as “based on condition A” may be based on both a condition A and a condition B without departing from the scope of the present disclosure. In other words, as used herein, the phrase “based on” shall be construed in the same manner as the phrase “based at least in part on.”

In the appended figures, similar components or features may have the same reference label. Further, various components of the same type may be distinguished by following the reference label by a dash and a second label that distinguishes among the similar components. If just the first reference label is used in the specification, the description is applicable to any one of the similar components having the same first reference label irrespective of the second reference label, or other subsequent reference label.

The description set forth herein, in connection with the appended drawings, describes example configurations and does not represent all the examples that may be implemented or that are within the scope of the claims. The term “example” used herein means “serving as an example, instance, or illustration,” and not “preferred” or “advantageous over other examples.” The detailed description includes specific details for the purpose of providing an understanding of the described techniques. These techniques, however, may be practiced without these specific details. In some instances, known structures and devices are shown in block diagram form in order to avoid obscuring the concepts of the described examples.

The description herein is provided to enable a person having ordinary skill in the art to make or use the disclosure. Various modifications to the disclosure will be apparent to a person having ordinary skill in the art, and the generic principles defined herein may be applied to other variations without departing from the scope of the disclosure. Thus, the disclosure is not limited to the examples and designs described herein, but is to be accorded the broadest scope consistent with the principles and novel features disclosed herein.

What is claimed is:

1. A method for wireless communications at a device, comprising:
receiving, during a first period, a first packet comprising a set of segments, wherein a segment of the set of segments comprises a cyclic redundancy check;
determining a corruption of one or more segments of the set of segments of the first packet based at least in part on the receiving;
processing the one or more segments of the set of segments of the first packet based at least in part on the corruption of the one or more segments of the first packet;
receiving, during a second period, a second packet based at least in part on the corruption of the one or more segments of the set of segments of the first packet, the second packet comprising one or more of the segments of the set of segments of the first packet;
processing the one or more segments of the set of segments of the first packet received in the second packet; and
transmitting a positive acknowledgment indicating a reception of all segments of the set of segments based at least in part on the first packet and the second packet.

2. The method of claim 1, wherein transmitting a negative acknowledgement based at least in part on the corruption of the one or more segments of the first packet, wherein receiving the second packet comprises:
receiving, during the second period, the second packet based at least in part on the negative acknowledgement.

3. The method of claim 1, wherein each segment of the set of segments comprises a cyclic redundancy check.

4. The method of claim 1, further comprising:
determining that each segment of the set of segments of the first packet comprises a cyclic redundancy check; and
decoding the cyclic redundancy check of each segment of the set of segments,
wherein determining the corruption of the one or more segments of the set of segments of the first packet is based at least in part on the decoding.

5. The method of claim 1, further comprising:
decoding the cyclic redundancy check of the segment of the set of segments of the first packet; and
decoding an additional cyclic redundancy check of the first packet,
wherein determining the corruption of one or more segments of the set of segments of the first packet is based at least in part on one or more of decoding the cyclic redundancy check of the segment of the set of segments or decoding the additional cyclic redundancy check of the first packet.

6. The method of claim 1, further comprising:
determining a successful decoding of the cyclic redundancy check of the segment of the set of segments of the first packet;
determining an unsuccessful decoding of an additional cyclic redundancy check of the first packet; and
refraining from dropping the first packet based at least in part on the successful decoding of the cyclic redundancy check of the segment of the set of segments of the first packet,
wherein processing the one or more segments of the set of segments of the first packet is based at least in part on the refraining.

7. The method of claim 6, wherein processing the one or more segments of the set of segments of the first packet comprises:
outputting a representation of the segment of the set of segments of the first packet based at least in part on the successful decoding of the cyclic redundancy check of the segment.

8. The method of claim 7, wherein processing the one or more segments of the set of segments of the first packet comprises:
determining an unsuccessful decoding of a second cyclic redundancy check of a second segment of the set of segments of the first packet; and
discarding the second segment based at least in part on the unsuccessful decoding of a second cyclic redundancy check.

9. The method of claim 7, wherein processing the one or more segments of the set of segments of the first packet comprises:
determining an unsuccessful decoding of a second cyclic redundancy check of a second segment of the set of segments of the first packet; and
performing a packet loss concealment operation based at least in part on the unsuccessful decoding of a second cyclic redundancy check.

10. The method of claim 1, further comprising:
aggregating the one or more segments of the set of segments of the first packet and the one or more of the segments of the set of segments of the first packet received in the second packet,
wherein the aggregating occurs at an upper layer of the device.

11. The method of claim 1, further comprising:
determining a sequence associated with one or more of the first packet or the second packet based at least in part on header information of one or more of the first packet or the second packet,
wherein transmitting the positive acknowledgement is based at least in part on the sequence associated with one or more of the first packet or the second packet.

12. The method of claim 11, further comprising:
identifying the header information in a real-time transport protocol header associated with one or more of the first packet or the second packet.

13. The method of claim 1, wherein one or more of the first packet or the second packet comprises an advanced audio distribution profile packet.

14. The method of claim 1, wherein one or more of the first packet or the second packet comprises an audio packet or a video packet, or a combination thereof.

15. A method for wireless communications at a device, comprising:
generating a packet;
segmenting the packet into a set of segments;
appending a cyclic redundancy check to one or more segments of the set of segments based at least in part on segmenting the packet into the set of segments; and
transmitting, during a first period, the packet comprising the set of segments to a device.

16. The method of claim 15, further comprising:
receiving a negative acknowledgement associated with transmitting the packet; and
transmitting, during a second period, a second packet to the device, the second packet comprising the set of segments transmitted in the packet,
wherein transmitting the second packet is based at least in part on receiving the negative acknowledgement.

17. The method of claim 15, further comprising:
appending an additional cyclic redundancy check to the first packet.

18. The method of claim 15, further comprising:
receiving a positive acknowledgment indicating a reception of all segments of the set of segments based at least in part on the first packet and the second packet; and
refraining from transmitting a third packet comprising one or more of the segments of the set of segments of the first packet or the second packet.

19. The method of claim 15, wherein each segment of the set of segments comprises a separate cyclic redundancy check.

20. An apparatus for wireless communications, comprising:
a processor,
memory coupled with the processor; and
instructions stored in the memory and executable by the processor to cause the apparatus to:
receive, during a first period, a first packet comprising a set of segments, wherein a segment of the set of segments comprises a cyclic redundancy check;
determine a corruption of one or more segments of the set of segments of the first packet based at least in part on the receiving;
process the one or more segments of the set of segments of the first packet based at least in part on the corruption of the one or more segments of the first packet;
receive, during a second period, a second packet based at least in part on the corruption of the one or more segments of the set of segments of the first packet, the second packet comprising one or more of the segments of the set of segments of the first packet;
process the one or more segments of the set of segments of the first packet received in the second packet; and
transmit a positive acknowledgment indicating a reception of all segments of the set of segments based at least in part on the first packet and the second packet.
